(19) United States
(12) Patent Application Publication
(10) Pub. No.: US 2024/0164217 A1
(43) Pub. Date: May 16, 2024

(54) PIEZOELECTRIC CERAMIC STACKED STRUCTURE

(71) Applicant: KOREA ATOMIC ENERGY RESEARCH INSTITUTE, Daejeon (KR)

(72) Inventors: Min Ku LEE, Daejeon (KR); Kyu Hyun PARK, Daejeon (KR); Gyoung Ja LEE, Daejeon (KR); Byung Hoon KIM, Daejeon (KR); Jin Ju PARK, Daejeon (KR)

(21) Appl. No.: 18/371,425

(22) Filed: Sep. 21, 2023

(30) Foreign Application Priority Data
Nov. 16, 2022 (KR) 10-2022-0153850

(51) Int. Cl. H10N 30/50; C04B 35/26; C04B 35/495; C04B 35/64; G01P 15/09; H10N 30/053; H10N 30/853

(52) U.S. Cl. CPC H10N 30/50; C04B 35/2683; C04B 35/495; C04B 35/64; G01P 15/0907; H10N 30/053; H10N 30/8542; H10N 30/8561; C04B 2235/3224; C04B 2235/3236; C04B 2235/3249; C04B 2235/3255; C04B 2235/3274

(57) ABSTRACT

The present invention relates to a piezoelectric ceramic stacked structure, and the piezoelectric ceramic stacked structure includes at least one first layer including a KNN-based ceramic; and at least one second layer including a BFO-based ceramic, wherein a ratio of a number (n1) of the first layers stacked to a number (n2) of the second layers stacked in the piezoelectric ceramic stacked structure satisfies Equation (1) below:

0.8×|q|/|p|≤n1/n2≤1.2×|q|/|p| (1)
(Equation (1) is as defined in the Description).

### CROSS REFERENCE TO RELATED APPLICATION

The present application claims priority to Korean Patent Application No. 10-2022 0153850, filed Nov. 16, 2022, the entire contents of which is incorporated herein for all purposes by this reference.

### BACKGROUND OF THE INVENTION

### Field of the Invention

The present invention relates to a piezoelectric ceramic stacked structure and a method for manufacturing the piezoelectric ceramic stacked structure.

### Description of the Related Art

Conventionally, various materials such as ceramics, single crystals, thick films and thin films have been developed as piezoelectric materials used in piezoelectric devices. Among them, piezoelectric ceramics made of PbZrO₃—PbTiO₃(PZT), a lead-containing perovskite ferroelectric, has excellent piezoelectric properties and has been widely used in various sensors, actuators, and transducers. Until now, piezoelectric materials containing lead (Pb), typically Pb(Zr,Ti)O₃(PZT), are widely used throughout the industry, such as fuel injectors, precision sensors, and actuators. However, lead has a low melting point and generates a significant amount of fumes at temperatures of 500 to 600° C., acting on the nervous system through the human respiratory system. As a result, since 2002, the use of lead (Pb) has been severely restricted as the European Union (EU)'s Restriction of Hazardous Substance Directive (RoHS) has been strongly enforced around the world.

Accordingly, research on the development of lead-free piezoelectric materials to replace lead-containing piezoelectric materials has been actively conducted. Representative examples include (K,Na)NbO₃-based piezoelectric ceramics (KNN-based piezoelectric ceramics), (Bi,Na)TiO₃-based piezoelectric ceramics (BNT-based piezoelectric ceramics), BaTiO₃-based piezoelectric ceramics (BT-based piezoelectric ceramics), and BiFeO₃-based piezoelectric ceramics (BFO-based piezoelectric ceramic). Among them, in the case of BNT-based piezoelectric ceramics, the polarization extinction temperature (Td) is as low as 200° C., and in the case of BT-based piezoelectric ceramics, the Curie temperature (Tc) is less than 120° C., which has the disadvantage of low operating temperature, making commercialization difficult. On the other hand, in the case of pure KNN and BFO piezoelectric ceramics, the Curie temperatures (Tc) are as high as 420° C. and 820° C., and in the case of recently developed materials, excellent properties comparable to the piezoelectric properties (d₃₃) of the existing PZT have been recently reported, and thus, it is highly likely to be commercialized as a lead-free piezoelectric material.

However, KNN-based and BFO-based lead-free piezoelectric ceramics have limitations in their use at high temperatures because their piezoelectric properties change with temperature, such as decreasing or increasing piezoelectric properties when the temperature increases. This is because material structural properties such as phase structure and lattice structure of KNN-based and BFO-based piezoelectric ceramics do not remain constant and change when the temperature increases. Due to these problems, it is difficult to commercialize lead-free piezoelectric ceramics.

### SUMMARY OF THE INVENTION

The present invention is a method for solving the temperature instability of lead-free piezoelectric ceramics, and has an object to provide a piezoelectric ceramic stacked structure in which piezoelectric properties are maintained constant even at high temperatures by stacking KNN-based ceramics whose piezoelectric properties decrease as the temperature increases and BFO-based ceramics whose piezoelectric properties increase as the temperature increases.

As a result of repeated research, the inventors of the present invention have found that the above-described technical problem can be solved by a piezoelectric ceramic stacked structure including at least one first layer including a KNN-based ceramic; and at least one second layer including a BFO-based ceramic, wherein a ratio of a number (n₁) of the first layers stacked to a number (n₂) of the second layers stacked in the piezoelectric ceramic stacked structure satisfies Equation (1) below, and have come to complete the present invention.

0.8×|q|/|p|≤n₁/n₂≤1.2×|q|/|p| (1)

In Equation (1), |p| represents an absolute value of a decrease rate (p) of a charge sensitivity according to a temperature of the first layer, and |q| represents an absolute value of an increase rate (q) of a charge sensitivity according to a temperature of the second layer, and the decrease rate (p) of the charge sensitivity according to the temperature of the first layer and the increase rate (q) of the charge sensitivity according to the temperature of the second layer are slope values of a straight line obtained by approximating the charge sensitivity according to the temperature within a temperature range from room temperature (25° C.) to a Curie temperature (Tc) of the KNN-based ceramic by a method of least squares.

The piezoelectric ceramic stacked structure of the present invention may maintain constant piezoelectric and sensitivity properties at an initial room temperature within ±10% up to about 300° C.

### BRIEF DESCRIPTION OF THE DRAWINGS

FIG. 1 is a piezoelectric accelerometer of Experimental Example 2.

FIG. 2 is a graph of charge sensitivity according to temperature in Example 1 and Comparative Examples 1 to 4.

FIG. 3 is a graph of charge sensitivity according to temperature in Comparative Examples 1 and 2.

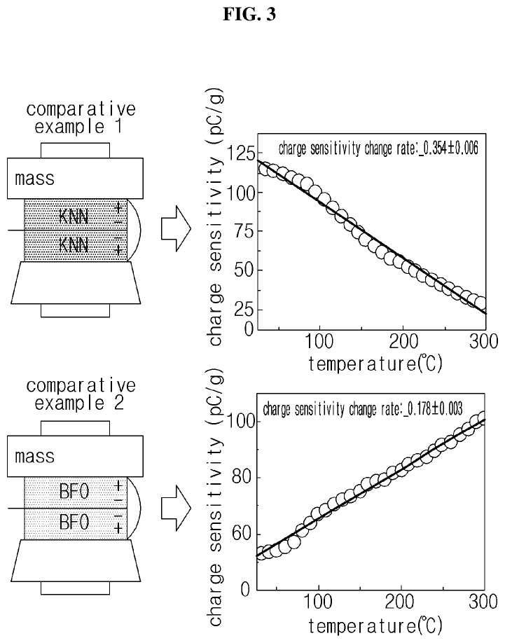

### DETAILED DESCRIPTION OF THE INVENTION

The present invention provides a piezoelectric ceramic stacked structure. Hereinafter, the piezoelectric ceramic stacked structure of the present invention will be described in detail.

The term “piezoelectric” in the present specification refers to an action of mutual conversion between mechanical energy and electrical energy through a medium of a piezoelectric body, and refers to an effect of generating electricity when pressure or vibration (mechanical energy) is applied. Indices indicating such piezoelectric performance include piezoelectric constants (d₃₃ and d₃₁), etc. In this case, the piezoelectric constant refers to the degree displaced when an electric field (V/m) is applied, or vice versa, and the larger the piezoelectric constant, the greater the advantage of enabling micro-displacement control.

In one embodiment of the present invention, a piezoelectric ceramic stacked structure may include at least one first layer including a KNN-based ceramic; and at least one second layer including a BFO-based ceramic, wherein a ratio of a number (n₁) of the first layers stacked to a number (n₂) of the second layers stacked in the piezoelectric ceramic stacked structure may satisfy Equation (1) below.

0.8×|q|/|p|≤n₁/n₂≤1.2×|q|/|p| (1)

In Equation (1), |p| represents an absolute value of a decrease rate (p) of a charge sensitivity according to a temperature of the first layer, and |q| represents an absolute value of an increase rate (q) of a charge sensitivity according to a temperature of the second layer.

The decrease rate (p) of the charge sensitivity according to the temperature of the first layer and the increase rate (q) of the charge sensitivity according to the temperature of the second layer are slope values of a straight line obtained by approximating the charge sensitivity according to temperature within a temperature range from room temperature (25° C.) to a Curie temperature (Tc) of the KNN-based ceramic by a method of least squares.

In one embodiment of the present invention, the KNN-based ceramic may include a ceramic represented by (K_{b}Na_{(1-b)})NbO₃ (where 0≤b≤1). KNN-based piezoelectric ceramics developed to date may have the Curie temperature of 200 to 500° C. In addition, the KNN-based piezoelectric ceramic may simultaneously have excellent piezoelectric properties with a piezoelectric constant (d₃₃) of 150 to 650 pC/N. The KNN-based ceramic of the present invention is a lead-free piezoelectric ceramic that can replace the existing PZT piezoelectric ceramic, and thus the KNN-based ceramic can prevent environmental pollution caused by lead.

In one embodiment of the present invention, the KNN-based ceramic may further include at least one selected from the group consisting of Li, Sb, Ta, CaZrO₃, SrZrO₃, BaZrO₃, CaTiO₃, SrTiO₃, BaTiO₃, Bi_{0.5}(Na_{c1}K_{c2}Li_{(1-c1-c2)})_{0.5}ZrO₃ (where 0≤c1≤1, 0≤c2≤1, 0≤c1+c2≤1), Bi_{0.5}(Na_{c1}K_{c2}Li_{(1-c1-c2)})_{0.5}TiO₃ (where 0≤c1≤1, 0≤c2≤1, 0≤c1+c2≤1), Bi_{0.5}Ag_{0.5}ZrO₃, Bi_{0.5}(Na_{c1}K_{c2}Li_{(1-c1-c2)})_{0.5}HfO₃ (where 0≤c1≤1, 0≤c2≤1, 0≤c1+c2≤1), Bi_{0.5}Ag_{0.5}HfO₃, BiScO₃, BiGaO₃, and BiFeO₃, as a dopant.

In one embodiment of the present invention, the KNN-based ceramic may be represented by Formula 1 below.

(1−a1-a2)(K_{b}Na_{(1-b)})NbO₃-a1Bi_{0.5}(Na_{c1}K_{c2}Li_{(1-c1-c2)})_{0.5}ZrO₃-a2BiScO₃ <Formula 1>

(where 0≤a1≤1, 0≤a2≤1, 0≤a1+a2≤1, 0≤b≤1, 0≤c1≤1, 0≤c2≤1, 0≤c1+c2≤1)

In Formula 1, a1 may be 0.01 to 0.05, 0.02 to 0.04, or 0.03. If Bi_{0.5}(Na_{c1}K_{c2}Li_{(1-c1-c2)})_{0.5}ZrO₃ (0≤c1≤1, 0≤c2≤1, 0≤c1+c2≤1) is included in (K_{b}Na_{(1-b)})NbO₃ so that a1 satisfies the above range, the KNN-based ceramic may have excellent piezoelectric properties.

In Formula 1, a2 may be 0.005 to 0.015, 0.007 to 0.013, 0.009 to 0.011, or 0.01. If BiScO₃ is included in (K_{b}Na_{(1-b)})NbO₃ so that a2 satisfies the above range, the KNN-based ceramic may have excellent piezoelectric properties.

In Formula 1, c1+c2 may be 0.85 to 0.97, 0.87 to 0.95, 0.89 to 0.92, or 0.9. If c1+c2 satisfies the above range, the KNN-based ceramic may have excellent piezoelectric properties.

In one embodiment of the present invention, the KNN-based ceramic is composed of a mixed phase structure including at least one of orthorhombic crystal system, tetragonal crystal system, trigonal crystal system (also referred to as “rhombohedral crystal system”), and the like. The piezoelectric properties of the KNN-based ceramic of the present invention may decrease as the temperature increases regardless of the composition of the phase.

The BFO-based ceramic of the present invention may include BiFeO₃ as a basis, and is also referred to as a BFO-based piezoelectric ceramic. The BFO-based piezoelectric ceramics developed to date may have the Curie temperature of 400 to 830° C. In addition, the BFO-based piezoelectric ceramic may have a remanent polarization of about 10 to 40 μC/cm². In addition, the BFO-based piezoelectric ceramic may have a piezoelectric constant (d₃₃) of 50 to 400 pC/N. The BFO-based piezoelectric ceramic of the present invention is a lead-free piezoelectric ceramic that can replace the existing PZT piezoelectric ceramic.

In one embodiment of the present invention, the BFO-based ceramic may be represented by Formula 2 below.

(1−d)BiFeO₃-dBaTiO₃ (where 0≤d≤1). <Formula 2>

In Formula 2, d may be 0.2 to 0.4, 0.25 to 0.35, or 0.3. If BaTiO₃ is included in BiFeO₃ so that d satisfies the above range, the BFO-based ceramic may have a high Curie temperature and a high piezoelectric constant.

The BFO-based ceramic represented by Formula 2 has a mixed phase structure including at least one of trigonal crystal system (also referred to as “rhombohedral crystal system”), pseudocubic crystal system, and the like. The piezoelectric properties of the BFO-based ceramic may increase as the temperature increases regardless of the composition of the phase.

In one embodiment of the present invention, the piezoelectric ceramic stacked structure may be lead-free. Since the piezoelectric ceramic stacked structure does not contain lead, environmental pollution due to lead may be prevented.

In one embodiment of the present invention, each thickness of the first layer including the KNN-based ceramic and the second layer including the BFO-based ceramic is independently 0.01 mm to 10 mm, 0.1 mm to 5 mm, or 0.5 mm to 2.5 mm, most preferably 1 mm. When the thickness of each of the first layer and the second layer satisfies the above range, each layer can effectively function as a piezoelectric ceramic, and it can be economical because less ceramic powder is used.

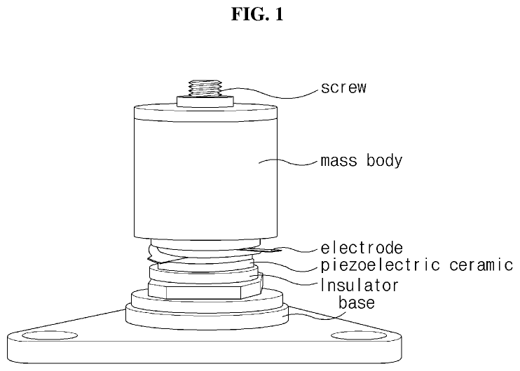

In one embodiment of the present invention, the temperature-dependent piezoelectric properties of the piezoelectric ceramic stacked structure of the present invention can be found by measuring the temperature-dependent charge sensitivity (Sq). The charge sensitivity according to temperature can be measured through a piezoelectric accelerometer as shown in FIG. 1. A piezoelectric accelerometer is a sensor that detects vibration, acceleration, and shock of an object by using a piezoelectric effect. The piezoelectric accelerometer of the present invention is a compression mode in which disc-shaped piezoelectric materials are arranged parallel to the vibration direction, that is, to detect acceleration in a direction parallel to the polarization direction. The basic structure of the piezoelectric accelerometer is shown in FIG. 1.

That is, as shown in FIG. 1, in the piezoelectric accelerometer of the present invention, an insulator may be stacked on a base, and then a piezoelectric ceramic stacked structure to be measured, an electrode, a mass body, and a screw may be sequentially stacked.

In one embodiment of the present invention, in the piezoelectric ceramic stacked structure, the first layer and the second layer may be alternately stacked. In this case, each layer must be stacked in a direction parallel to the vibration to realize the complex properties of the piezoelectric ceramic stacked structure. In addition, each polarized layer (specimen) must have a structure electrically connected in parallel.

By including the piezoelectric ceramic stacked structure of the present invention in the piezoelectric accelerometer, the charge sensitivity of the piezoelectric ceramic stacked structure can be measured. In addition, the piezoelectric accelerometer of the present invention can measure charge sensitivity even when the temperature changes. The charge sensitivity (Sq) obtained through the piezoelectric accelerometer has a relational expression as shown in Equation (2) below.

Sq=n·mₛ·d₃₃·g (2)

In Equation (2), n is the number of piezoelectric ceramics are stacked, mₛ is the mass of a mass body, d₃₃ is the static piezoelectric constant, and g is the gravitational acceleration.

Through the above equation, the (static) piezoelectric constant (d₃₃) can be obtained from the charge sensitivity (Sq). That is, the piezoelectric properties of the ceramic stacked structure can be obtained through the piezoelectric accelerometer.

According to the above method, the KNN-based ceramic layer is heated from room temperature to the Curie temperature, and the charge sensitivity at each temperature can be measured. The obtained temperature-dependent charge sensitivity data can be graph plotted with temperature as a variable, and the slope can be obtained through linear regression analysis using the method of least squares in the plotted data. The decrease rate (p) of the charge sensitivity according to the temperature of the first layer and the increase rate (q) of the charge sensitivity according to the temperature of the second layer can be obtained through the slope of the charge sensitivity graph according to the temperatures of the first layer and second layer obtained through the above method. Then, the ratio of the decrease rate (p) of the charge sensitivity according to the temperature of the first layer and the increase rate (q) of the charge sensitivity according to the temperature of the second layer can be obtained.

In one embodiment of the present invention, the first layers and the second layers may be stacked such that the ratio of the number (n₁) of the first layers stacked and the number (n₂) of the second layers stacked in the piezoelectric ceramic stacked structure satisfies the following equation (1). In this case, since each layer is stacked so that the (+) pole and the (−) pole inside the layer face each other, each layer can be distinguished even if the same kind of layers are stacked.

0.8×|q|/|p|≤n₁/n₂≤1.2×|q|/|p| (1)

In one embodiment of the present invention, the difference between the number (n₁) of the first layers stacked and the number (n₂) of the second layers stacked to satisfy Equation (1) may be −1, 0, or 1. In this case, the first layers and the second layers may be alternately stacked. In the piezoelectric ceramic stacked structure of the present invention, when the first layers and the second layers are alternately stacked, the effect of maintaining constant piezoelectric properties even at high temperatures of the piezoelectric ceramic stacked structure may be excellent.

In one embodiment of the present invention, the absolute value (|p|) of the decrease rate (p) of the charge sensitivity according to the temperature of the first layer may be 0.3 to 0.4 pC/° C.g, 0.33 to 0.37 pC/° C.g, or 0.35 pC/° C.g.

In one embodiment of the present invention, the absolute value (|q|) of the increase rate (q) of the charge sensitivity according to the temperature of the second layer may be 0.15 to 0.2 pC/° C.g, 0.16 to 0.19 pC/° C.g, or 0.175 pC/° C.g.

In addition, the present invention provides a method for manufacturing the piezoelectric ceramic stacked structure. Hereinafter, in one embodiment of the present invention, a method for manufacturing a piezoelectric ceramic stacked structure will be described in detail for each step.

one embodiment of the present invention, the method for manufacturing a piezoelectric ceramic stacked structure includes forming a precursor powder of a KNN-based ceramic by weighing a KNN-based precursor mixture including sodium precursor powder, potassium precursor powder, and niobium precursor powder, and then mixing and calcining the mixture.

The step may be the step of solid-state synthesis of the precursor powder of the KNN-based ceramic having the composition of Formula 1 above.

In this case, the sodium precursor powder, potassium precursor powder, and niobium precursor powder may be, for example, ceramic powders of Na₂CO₃, K₂CO₃, and Nb₂O₅, but are not limited thereto, and other types of ceramic powder may be used for solid phase synthesis of the precursor powder of the KNN-based ceramic. For example, oxides, carbonates, oxalates, hydrogencarbonates, hydroxides, and the like containing the above elements may be weighed and mixed.

In addition, the method for manufacturing a piezoelectric ceramic stacked structure includes forming a precursor powder of a BFO-based ceramic by weighing a BFO-based precursor mixture including bismuth precursor powder, iron precursor powder, barium precursor powder, and titanium precursor powder, and then mixing and calcining the mixture.

The step may be the step of solid-phase synthesizing the precursor powder of the BFO-based ceramic having the composition of Formula 2 above.

In this case, the bismuth precursor powder, iron precursor powder, barium precursor powder, and titanium precursor powder may be ceramic powders of Bi₂O₃, Fe₂O₃, BaCO₃ and TiO₂, but are not limited thereto, and other types of ceramic powder may be used for solid-phase synthesis of the precursor powder of the BFO-based ceramic. For example, oxides, carbonates, oxalates, hydrogencarbonates, hydroxides and the like containing the above elements may be weighed and mixed.

In one embodiment of the present invention, the calcination may be performed at a temperature of about 700 or more and 1100° C. for 0.5 hours or more and 10 hours or less, but the present invention is not limited to this time range and may be arbitrarily shortened or extended as desired.

In one embodiment of the present invention, the method may include forming at least one first layer including the KNN-based ceramic represented by Formula 1 below by sintering the precursor powder of the KNN-based ceramic and forming at least one second layer including the BFO-based ceramic represented by Formula 2 below by sintering the precursor powder of the BFO-based ceramic.

In one embodiment of the present invention, the sintering temperature may be 1000 to 1250° C., or 1100 to 1200° C. If the sintering temperature is less than the above lower limit temperature, the raw material may not be sufficiently sintered and the ceramic may not have appropriate properties. In addition, if the sintering temperature exceeds the above upper limit temperature, a part of the element constituting the ceramic is precipitated and the piezoelectric properties are deteriorated.

In one embodiment of the present invention, the obtained precursor powder of the KNN-based ceramic and the precursor powder of the BFO-based ceramic may be pulverized with a ball mill and molded into a desired shape by adding a binder. The pulverizing and molding means known in the art of piezoelectric ceramics may be used for the pulverizing and molding.

In one embodiment of the present invention, the sintering time is 0.5 to 24 hours, 1 to 10 hours. If the sintering time is shorter than the lower limit of the sintering time, the molded body may not be completely sintered. In addition, if the sintering time is longer than the upper limit of the sintering time, some of the elements constituting the ceramic may be volatilized.

In one embodiment of the present invention, the method for manufacturing a piezoelectric ceramic stacked structure may further include a polarization treatment process after the sintering process. An electrode is formed on the ceramic obtained by the polarization treatment step, and polarization treatment is performed. By the polarization treatment, the directions of spontaneous polarization in the ceramic are aligned, and piezoelectric properties are developed. For the polarization treatment, a known polarization treatment generally used in the manufacturing of piezoelectric ceramics may be used. For example, the sintered body in which the electrode is formed is maintained at a temperature of not less than room temperature and not more than 200° C. or less in a silicon bath or the like, and a voltage of 1 kV/mm or more and about 6 kV/mm is applied to the sintered body. Accordingly, a piezoelectric ceramic having piezoelectric properties can be obtained.

In one embodiment of the present invention, in the method for manufacturing a piezoelectric ceramic stacked structure, a first layer including a disk-shaped KNN-based ceramic formed through the above process and a second layer including a BFO-based ceramic may be stacked. In this case, each layer must be stacked in a direction parallel to the vibration to realize the complex properties of the piezoelectric ceramic stacked structure. In addition, each polarized layer (specimen) must have a structure electrically connected in parallel.

Details of the piezoelectric ceramic stacked structure manufactured according to the method for manufacturing the piezoelectric ceramic stacked structure are the same as described above.

### EXAMPLES

Hereinafter, the present invention will be described in more detail through Manufacturing Examples and Examples. However, these Manufacturing Examples are only for helping the understanding of the present invention, and the scope of the present invention is not limited to these Manufacturing Examples and Examples in any sense.

### Manufacturing Example

After quantifying the ceramic powders of K₂CO₃, Na₂CO₃, Nb₂O₅, Sc₂O₃, TiO₂, Li₂CO₃, Bi₂O₃, BaCO₃, Fe₂O₃ and ZrO₂ of the purity commonly used for industrial use to be 0.96(K,Na)NbO₃-0.03Bi_{0.5}(Na_{0.7}K_{0.2}Li_{0.1})_{0.5}ZrO₃-0.01BiScO₃ and 0.70BiFeO₃-0.30BaTiO₃, they were wet-mixed for 24 hours by a ball milling method to prepare a slurry. For the subsequent solid state reaction, the slurry was dried and then calcinated at 850° C. for 3 hours. A binder for molding was added to the calcined powder and sieved. The sieved powder was molded into a disk shape by applying a pressure of about 100 Mpa using a pressure molding machine, put in an electric furnace, and sintered at about 1100° C. for 3 hours to manufacture a disk with an outer diameter of 8.5 mm, an inner diameter of 3.9 mm, and a thickness of 1 mm. An electrode was formed on the piezoelectric ceramic obtained in the above process, and a polarization treatment was performed by maintaining a temperature of not less than room temperature and not more than 200° C. in a silicon bath and applying a voltage of about 3 kV/mm. Through the above-described method, a first layer including a KNN-based ceramic having a formula of 0.96(K,Na)NbO₃-0.03Bi_{0.5}(Na_{0.7}K_{0.2}Li_{0.1})_{0.5}ZrO₃-0.01BiScO₃ and a second layer having a BFO-based ceramic having a formula of 0.70BiFeO₃-0.30BaTiO₃ were obtained.

### Example 1

According to the following Experimental Example, the sensitivity (piezoelectric property) according to the temperature of the KNN-based ceramic was measured, and the slope of the charge sensitivity according to the temperature of the first and second layers was derived using OriginPro 8G® (OriginLab Corporation, North Hampton, Massachusetts, USA) and Excel® (version 2007, Microsoft Corporation). The decrease rate (slope of the linear regression line, p) of the charge sensitivity according to the temperature of the first layer was −0.354±0.006 pC/° C. g, and the increase rate (slope of the linear regression line, q) of the charge sensitivity according to the temperature of the second layer was 0.178±0.003 pC/° C.g. Accordingly, since |q|/|p| was about 0.5028, a total of three layers were stacked by alternating one first layer between two second layers so that n₁/n₂, which was the ratio of the number (n₁) of the first layers stacked to the number (n₂) of the second layers stacked, was a value of 0.5, which lies between 0.4022, corresponding to 0.8×|q|/|p|, and 0.6034, corresponding to 1.2×|q|/|p|, that is, the ratio of 1:2. In this case, each layer was stacked so that the same poles, that is, (+) poles and (−) poles face each other, or were stacked so as to be connected in parallel by connecting with electrodes.

### Comparative Example 1

It was carried out in the same manner as in Example 1, except that a total of two layers were stacked only with the first layer.

### Comparative Example 2

It was carried out in the same manner as in Example 1, except that a total of two layers were stacked only with the second layer.

### Comparative Example 3

It was carried out in the same manner as in Example 1, except that a total of two layers were stacked so that the first layer and the second layer were stacked at a ratio of 1:1.

### Comparative Example 4

It was carried out in the same manner as in Example 1, except that a total of three layers were stacked so that the first layer and the second layer were alternately stacked at a ratio of 2:1.

### Experimental Examples

### Experimental Example 1: Measurement of Electrical/Piezoelectric Properties

The electrical/piezoelectric properties of the first layer and second layer at room temperature were measured and were shown in Table 1 below.

Remanent polarization and coercive field values were measured using a ferroelectric hysteresis curve measurement equipment (TF analyzer, aixACCT System) by connecting + poles and − poles to both ends of the first and second layer ceramic electrodes, putting them in a container of silicon oil for insulation, and then using a 10 Hz triangular wave in an electric field of 70 kV/cm at room temperature. Dielectric constant, Curie temperature and dielectric loss were measured using HP Impedance Analyzer HP4294A. The static piezoelectric constant (d₃₃) was measured by applying a force of 0.25 N using equipment (piezo-d33-meter, ZJ-6B, IACAS), and large-signal piezoelectric constant (d₃₃*) was measured using equipment (TF analyzer, aixACCT System).

TABLE 1

| Material property | | KNN-based | BFO-based |
|---|---|---|---|
| Remanent polarization | Pᵣ(μC/cm²) | 20.5 | 19.1 |
| Coercive Field | E_{C}(kV/cm) | 13.8 | 26.2 |
| dielectric constant | εᵣ(—) | 1113 | 643 |
| dielectric loss | tanδ(—) | 0.03 | 0.07 |
| Large-signal | d₃₃*(pm/V) | 441.1 | 278.0 |
| piezoelectric constant | | | |
| Static piezoelectric | d₃₃(pC/N) | 310.0 ± 4.8 | 165.2 ± 2.1 |
| constant | | | |
| Curie temperature | Tc(° C.) | 330.9 | 505.0 |

### Experimental Example 2: Measurement of Charge Sensitivity According to Temperature Change

In order to measure the change in piezoelectric properties according to temperature, charge sensitivity (Sq) was measured by a piezoelectric accelerometer sensor. As shown in FIG. 1, in the piezoelectric accelerometer, an insulator was stacked on a base, then a piezoelectric ceramic stacked structure to be measured, an electrode (Inconel 600), a mass body (Wc-Co alloy), and a screw (Inconel 600) were sequentially stacked.

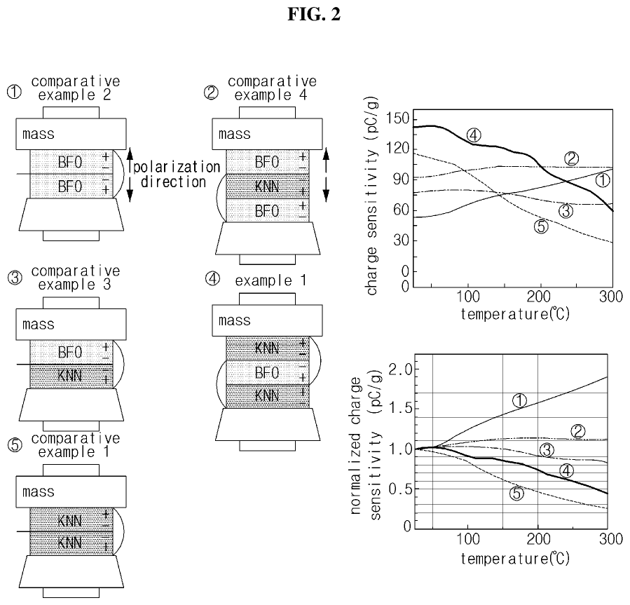

While replacing the piezoelectric ceramic stacked structures of Example 1 and Comparative Examples 1 to 4, the charge sensitivity curves according to temperature were obtained through the piezoelectric accelerometer and shown in FIG. 2.

According to FIG. 2, the piezoelectric ceramic stacked structure of Example 1 maintained a constant piezoelectric property at initial room temperature within ±10% up to about 300° C. or higher. Thus, it was confirmed that the piezoelectric ceramic stacked structure of Example 1 was superior in temperature stability to the piezoelectric ceramic stacked structures of Comparative Examples 1 to 4. It was confirmed that Comparative Examples 1 to 4, in which the material of the piezoelectric ceramic stacked structure was different or the stacked structure ratio was different, showed had different rates of change in sensitivity with temperature.

What is claimed is:

1. A piezoelectric ceramic stacked structure, comprising:
at least one first layer comprising a KNN-based ceramic; and
at least one second layer comprising a BFO-based ceramic,
wherein a ratio of a number (n₁) of the first layers stacked to a number (n₂) of the second layers stacked in the piezoelectric ceramic stacked structure satisfies Equation (1) below:
0.8×|q|/|p|≤n₁/n₂≤1.2×|q|/|p| (1)
in Equation (1), |p| represents an absolute value of a decrease rate (p) of a charge sensitivity according to a temperature of the first layer, and |q| represents an absolute value of an increase rate (q) of a charge sensitivity according to a temperature of the second layer, and
the decrease rate (p) of the charge sensitivity according to the temperature of the first layer and the increase rate (q) of the charge sensitivity according to the temperature of the second layer are slope values of a straight line obtained by approximating the charge sensitivity according to the temperature within a temperature range from room temperature (25° C.) to a Curie temperature (Tc) of the KNN-based ceramic by a method of least squares.

2. The piezoelectric ceramic stacked structure of claim 1, wherein the KNN-based ceramic comprises a ceramic represented by (K_{b}Na_{(1-b)})NbO₃ (where 0≤b≤1).

3. The piezoelectric ceramic stacked structure of claim 2, wherein the KNN-based ceramic further comprises at least one selected from the group consisting of Li, Sb, Ta, CaZrO₃, SrZrO₃, BaZrO₃, CaTiO₃, SrTiO₃, BaTiO₃, Bi_{0.5}(Na_{c1}K_{c2}Li_{(1-c1-c2)})_{0.5}ZrO₃ (where 0≤c1≤1, 0≤c2≤1, 0≤c1+c2≤1), Bi_{0.5}(Na_{c1}K_{c2}Li_{(1-c1-c2)})_{0.5}TiO₃ (where 0≤c1≤1, 0≤c2≤1, 0≤c1+c2≤1), Bi_{0.5}Ag_{0.5}ZrO₃, Bi_{0.5}(Na_{c1}K_{c2}Li_{(1-c1-c2)})_{0.5}HfO₃ (where 0≤c1≤1, 0≤c2≤1, 0≤c1+c2≤1), Bi_{0.5}Ag_{0.5}HfO₃, BiScO₃, BiGaO₃, and BiFeO₃, as a dopant.

4. The piezoelectric ceramic stacked structure of claim 1, wherein the KNN-based ceramic is represented by Formula 1 below:
(1−a1-a2)(K_{b}Na_{(1-b)})NbO₃-a1Bi_{0.5}(Na_{c1}K_{c2}Li_{(1-c1-c2)})_{0.5}ZrO₃-a2BiScO₃ <Formula 1>
(where 0≤a1≤1, 0≤a2≤1, 0≤a1+a2≤1, 0≤b≤1, 0≤c1≤1, 0≤c2≤1, 0≤c1+c2≤1).

5. The piezoelectric ceramic stacked structure of claim 1, wherein the BFO-based ceramic is represented by Formula 2 below:
(1−d)BiFeO₃-dBaTiO₃ (where 0≤d≤1). <Formula 2>

6. The piezoelectric ceramic stacked structure of claim 5, wherein d is greater than or equal to 0.2 and less than or equal to 0.4.

7. The piezoelectric ceramic stacked structure of claim 1, wherein the piezoelectric ceramic stacked structure is lead-free.

8. The piezoelectric ceramic stacked structure of claim 1, wherein the first layer and the second layer are electrically connected in parallel.

9. The piezoelectric ceramic stacked structure of claim 1, wherein the absolute value (|p|) of the decrease rate (p) of the charge sensitivity according to the temperature of the first layer is 0.3 to 0.4 pC/° C.g.

10. The piezoelectric ceramic stacked structure of claim 1, wherein the absolute value (|q|) of the increase rate (q) of the charge sensitivity according to the temperature of the second layer is 0.15 to 0.2 pC/° C.g.

11. A method for manufacturing a piezoelectric ceramic stacked structure, comprising:
forming a precursor powder of a KNN-based ceramic by calcining a KNN-based precursor mixture comprising sodium precursor powder, potassium precursor powder, and niobium precursor powder;
forming a precursor powder of a BFO-based ceramic by calcining a BFO-based precursor mixture comprising bismuth precursor powder, iron precursor powder, barium precursor powder, and titanium precursor powder;
forming at least one first layer by sintering the precursor powder of the KNN-based ceramic;
forming at least one second layer by sintering the precursor powder of the BFO-based ceramic; and
forming a stacked structure including n₁ of the first layers and n₂ of the second layers
wherein a ratio of a number (n₁) of the first layers stacked to a number (n₂) of the second layers stacked satisfies Equation (1) below:
0.8×|q|/|p|≤n₁/n₂≤1.2×|q|/|p| (1)
in Equation (1), |p| represents an absolute value of a decrease rate (p) of a charge sensitivity according to a temperature of the first layer, and |q| represents an absolute value of an increase rate (q) of a charge sensitivity according to a temperature of the second layer, and
the decrease rate (p) of the charge sensitivity according to the temperature of the first layer and the increase rate (q) of the charge sensitivity according to the temperature of the second layer are slope values of a straight line obtained by approximating the charge sensitivity according to the temperature within a temperature range from room temperature (25° C.) to a Curie temperature (Tc) of the KNN-based ceramic by a method of least squares.

12. The method of claim 11, wherein the KNN-based ceramic comprises a ceramic represented by (K_{b}Na_{(1-b)})NbO₃ (where 0≤b≤1).

13. The method of claim 12, wherein the KNN-based ceramic further comprises at least one selected from the group consisting of Li, Sb, Ta, CaZrO₃, SrZrO₃, BaZrO₃, CaTiO₃, SrTiO₃, BaTiO₃, Bi_{0.5}(Na_{c1}K_{c2}Li_{(1-c1-c2)})_{0.5}ZrO₃ (where 0≤c1≤1, 0≤c2≤1, 0≤c1+c2≤1), Bi_{0.5}(Na_{c1}K_{c2}Li_{(1-c1-c2)})_{0.5}TiO₃ (where 0≤c1≤1, 0≤c2≤1, 0≤c1+c2≤1), Bi_{0.5}Ag_{0.5}ZrO₃, Bi_{0.5}(Na_{c1}K_{c2}Li_{(1-c1-c2)})_{0.5}HfO₃ (where 0≤c1≤1, 0≤c2≤1, 0≤c1+c2≤1), Bi_{0.5}Ag_{0.5}HfO₃, BiScO₃, BiGaO₃, and BiFeO₃, as a dopant.

14. The method of claim 11, wherein the KNN-based ceramic is represented by Formula 1 below:
(1−a1-a2)(K_{b}Na_{(1-b)})NbO₃-a1Bi_{0.5}(Na_{c1}K_{c2}Li_{(1-c1-c2)})_{0.5}ZrO₃-a2BiScO₃ <Formula 1>
(where 0≤a1≤1, 0≤a2≤1, 0≤a1+a2≤1, 0≤b≤1, 0≤c1≤1, 0≤c2≤1, 0≤c1+c2≤1).

15. The method of claim 11, wherein the BFO-based ceramic is represented by Formula 2 below:
(1−d)BiFeO₃-dBaTiO₃ (where 0≤d≤1). <Formula 2>

16. The method of claim 15, wherein d is greater than or equal to 0.2 and less than or equal to 0.4.

17. The method of claim 11, wherein the piezoelectric ceramic stacked structure is lead-free.

18. The method of claim 11, wherein the first layer and the second layer are electrically connected in parallel.

19. The method of claim 11, wherein the absolute value (|p|) of the decrease rate (p) of the charge sensitivity according to the temperature of the first layer is 0.3 to 0.4 pC/° C.g.

20. The method of claim 11, wherein the absolute value (|q|) of the increase rate (q) of the charge sensitivity according to the temperature of the second layer is 0.15 to 0.2 pC/° C.g.
